(19) United States
(12) Patent Application Publication
(10) Pub. No.: US 2024/0253158 A1
(43) Pub. Date: Aug. 1, 2024

(54) LASER PROCESSING APPARATUS AND METHOD OF MANUFACTURING SEMICONDUCTOR DEVICE

(71) Applicant: Mitsubishi Electric Corporation, Tokyo (JP)

(72) Inventors: Ryo KAMOSHIDA, Tokyo (JP); Tamio MATSUMURA, Tokyo (JP)

(73) Assignee: Mitsubishi Electric Corporation, Tokyo (JP)

(21) Appl. No.: 18/412,458

(22) Filed: Jan. 12, 2024

(30) Foreign Application Priority Data
Jan. 26, 2023 (JP) 2023-010184

(51) Int. Cl. B23K 26/146; B23K 26/14

(52) U.S. Cl. CPC B23K 26/146; B23K 26/1462

(57) ABSTRACT

A laser processing apparatus includes a stage having a wafer holding surface, a laser irradiation mechanism, and a nozzle. On the wafer holding surface, a semiconductor wafer having a first surface and a second surface opposite to the first surface is disposed such that the wafer holding surface faces the second surface. The laser irradiation mechanism applies a laser beam from a first surface side. The nozzle supplies a liquid from a second surface side.

### CROSS REFERENCE TO RELATED APPLICATIONS

This nonprovisional application is based on Japanese Patent Application No. 2023-010184 filed on Jan. 26, 2023 with the Japan Patent Office, the entire contents of which are hereby incorporated by reference.

### BACKGROUND OF THE INVENTION

### Field of the Invention

The present disclosure relates to a laser processing apparatus and a method of manufacturing a semiconductor device.

### Description of the Background Art

For example, WO 2018/116932 discloses a laser processing apparatus. The laser processing apparatus disclosed in WO 2018/116932 includes a holder, a liquid reservoir, a laser source, and a nozzle.

On the holder, a semiconductor wafer is disposed. The semiconductor wafer has a first surface facing the holder and a second surface opposite to the first surface. The semiconductor wafer has an outer circumferential portion located on the outer peripheral of the semiconductor wafer in plan view, and an inner circumferential portion located inside the outer circumferential portion in plan view.

In the liquid reservoir, a liquid is stored. The liquid stored in the liquid reservoir flows from the nozzle toward the first surface to form a liquid column. Also, the liquid that has reached the first surface forms a liquid layer on the first surface. A laser beam generated in the laser source is applied to the semiconductor wafer through the liquid column. Thus, the outer circumferential portion is separated from the semiconductor wafer. Debris occurs at a portion of the semiconductor wafer, which is irradiated with the laser beam, when the outer circumferential portion is separated from the semiconductor wafer, but the liquid layer reduces adhering of the debris to the first surface.

### SUMMARY OF THE INVENTION

In the laser processing apparatus disclosed in WO 2018/116932, debris also occurs on the second surface when the outer circumferential portion is separated from the semiconductor wafer, but adhering of the debris to the second surface is not reduced. The present disclosure provides a laser processing apparatus that can reduce adhering of debris to a second surface of a semiconductor wafer.

A laser processing apparatus of the present disclosure includes a stage having a wafer holding surface, a laser irradiation mechanism, and a nozzle. On the wafer holding surface, a semiconductor wafer having a first surface and a second surface opposite to first surface is disposed such that the wafer holding surface faces the second surface. The laser irradiation mechanism applies a laser beam from a first surface side. The nozzle supplies a liquid from a second surface side.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a semiconductor wafer 10.

FIG. 2 is a schematic sectional view of a laser processing apparatus 100.

FIG. 3 is a flowchart for manufacturing a semiconductor device using laser processing apparatus 100.

FIG. 4 is a sectional view for describing a preparation step S1.

FIG. 5 is a graph showing heights of debris that adhere to a second surface 10b when a liquid 51 is supplied from the second surface 10b side and when liquid 51 is not supplied from the second surface 10b side.

FIG. 6 is a schematic sectional view of a laser processing apparatus 200.

FIG. 7 is a schematic sectional view of a laser processing apparatus 300.

FIG. 8 is a schematic sectional view of a laser processing apparatus 400.

### DESCRIPTION OF THE PREFERRED EMBODIMENTS

### Embodiment 1

A laser processing apparatus according to Embodiment 1 will be described. The laser processing apparatus according to Embodiment 1 is referred to as a laser processing apparatus 100.

### Configuration of Laser Processing Apparatus 100

A configuration of laser processing apparatus 100 will be described below.

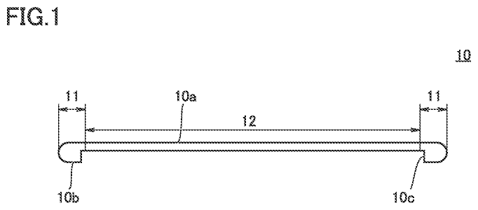

FIG. 1 is a sectional view of a semiconductor wafer 10. Semiconductor wafer 10 has a first surface 10a and a second surface 10b. First surface 10a and second surface 10b are end surfaces in the thickness direction of semiconductor wafer 10. Second surface 10b is opposite to first surface 10a. A material for semiconductor wafer 10 is, for example, monocrystalline silicon, but the material for semiconductor wafer 10 is not limited thereto. Although not shown, semiconductor wafer 10 has, for example, a circular shape in plan view.

Semiconductor wafer 10 has an outer circumferential portion 11 and an inner circumferential portion 12. Outer circumferential portion 11 is a portion located on the outer circumference of semiconductor wafer 10 in plan view. Inner circumferential portion 12 is a portion of semiconductor wafer 10, which is located inside outer circumferential portion 11 in plan view. In second surface 10b located at inner circumferential portion 12, a recess 10c is formed. In other words, second surface 10b located at inner circumferential portion 12 is recessed toward first surface 10a. In another respect, semiconductor wafer 10 has a thickness smaller than that of outer circumferential portion 11 at inner circumferential portion 12.

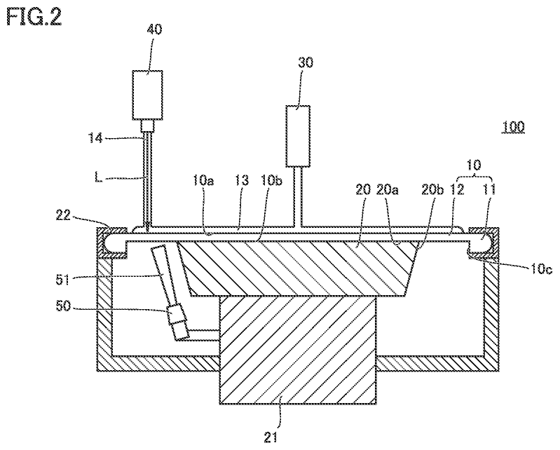

FIG. 2 is a schematic sectional view of laser processing apparatus 100. As shown in FIG. 2, laser processing apparatus 100 is used to separate outer circumferential portion 11 from semiconductor wafer 10. Laser processing apparatus 100 includes a stage 20, a driver 21, a clamping mechanism 22, a liquid supply mechanism 30, a laser irradiation mechanism 40, and a nozzle 50.

Stage 20 has a wafer holding surface 20a and a side surface 20b. Semiconductor wafer 10 is disposed on wafer holding surface 20a. More specifically, semiconductor wafer 10 is disposed on wafer holding surface 20a such that second surface 10b (the bottom surface of recess 10c) located at inner circumferential portion 12 faces wafer holding surface 20a. Semiconductor wafer 10 is held on stage 20 as second surface 10b located at inner circumferential portion 12 sticks to wafer holding surface 20a. Side surface 20b is contiguous to wafer holding surface 20a.

Stage 20 is disposed on driver 21. Driver 21 rotates stage 20 around the axis of rotation (not shown) running in the direction of the normal to wafer holding surface 20a. Clamping mechanism 22 clamps outer circumferential portion 11. Following the rotation of stage 20, clamping mechanism 22 rotates around the axis of rotation.

Liquid supply mechanism 30 supplies a liquid onto first surface 10a. As the liquid is supplied from liquid supply mechanism 30, a liquid layer 13 is formed on first surface 10a. Laser processing apparatus 100 may not include liquid supply mechanism 30.

Laser irradiation mechanism 40 irradiates an end of inner circumferential portion 12, which is located on the outer circumferential portion 11 side, with a laser beam L from the first surface 10a side in order to separate outer circumferential portion 11 from semiconductor wafer 10. Laser irradiation mechanism 40 may flow the liquid from a liquid reservoir (not shown) onto first surface 10a to form a liquid column 14. Laser beam L may be guided by liquid column 14. Specifically, laser beam L may propagate through liquid column 14 while being totally reflected by the surface of liquid column 14, thereby being applied to semiconductor wafer 10 from the first surface 10a side. When laser processing apparatus 100 does not include liquid supply mechanism 30, liquid layer 13 may be formed on first surface 10a as the liquid flowing for formation of liquid column 14 reaches first surface 10a.

Nozzle 50 sprays a liquid 51 from its opening. The opening edge of the opening of nozzle 50 has, for example, a circular shape, but the shape of the opening edge of the opening of nozzle 50 is not limited thereto. Liquid 51 sprayed from the opening of nozzle 50 is supplied from the second surface 10b side to semiconductor wafer 10. More specifically, liquid 51 is supplied from the second surface 10b side to a portion of semiconductor wafer 10, which is irradiated with laser beam L.

### Method of Manufacturing Semiconductor Device Using Laser Processing Apparatus 100

A method of manufacturing a semiconductor device using laser processing apparatus 100 will be described below.

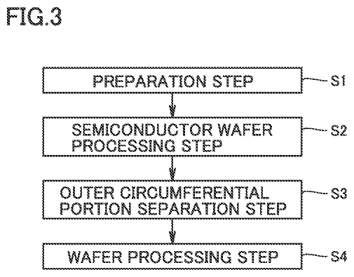

FIG. 3 is a flowchart for manufacturing a semiconductor device using laser processing apparatus 100. As shown in FIG. 3, the method of manufacturing a semiconductor device using laser processing apparatus 100 includes a preparation step S1, a semiconductor wafer processing step S2, an outer circumferential portion separation step S3, and a wafer processing step S4.

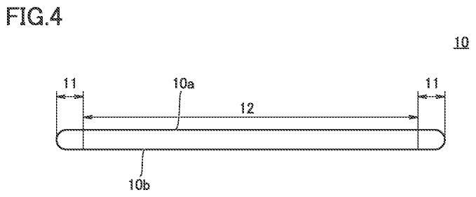

FIG. 4 is a sectional view for describing preparation step S1. As shown in FIG. 4, semiconductor wafer 10 is prepared in preparation step S1. Note that in semiconductor wafer 10 prepared in preparation step S1, recess 10c is not formed in second surface 10b located at inner circumferential portion 12.

Semiconductor wafer processing step S2 is performed after preparation step S1. In semiconductor wafer processing step S2, recess 10c is formed in second surface 10b located at inner circumferential portion 12. Recess 10c is formed by, for example, grinding of second surface 10b. Thus, semiconductor wafer 10 configured as shown in FIG. 1 is prepared.

Outer circumferential portion separation step S3 is performed after semiconductor wafer processing step S2. In outer circumferential portion separation step S3, outer circumferential portion 11 is separated from semiconductor wafer 10 with laser processing apparatus 100. In outer circumferential portion separation step S3, first, semiconductor wafer 10 is disposed on wafer holding surface 20a such that second surface 10b located at inner circumferential portion 12 faces wafer holding surface 20a, and second surface 10b located at inner circumferential portion 12 sticks to wafer holding surface 20a. Also, after semiconductor wafer 10 is disposed on wafer holding surface 20a, outer circumferential portion 11 is clamped by clamping mechanism 22.

In outer circumferential portion separation step S3, second, the rotation of stage 20 around the axis of rotation is started by driver 21. In outer circumferential portion separation step S3, third, laser irradiation mechanism 40 applies laser beam L from the first surface 10a side while stage 20 is rotating. Thus, outer circumferential portion 11 is separated from semiconductor wafer 10. At this time, debris occurs by melting of the portion of semiconductor wafer 10, irradiated with laser beam L, on first surface 10a. Since liquid layer 13 is formed on first surface 10a by the liquid supplied from liquid supply mechanism 30, the debris that has occurred on first surface 10a is unlikely to adhere to first surface 10a. Also, debris occurs on second surface 10b. Since nozzle 50 supplies liquid 51 to the portion of semiconductor wafer 10, irradiated with laser beam L, from the second surface 10b side, the debris that has occurred on second surface 10b is unlikely to adhere to first surface 10a.

Wafer processing step S4 is performed after outer circumferential portion separation step S3. Semiconductor wafer 10 with outer circumferential portion 11 separated therefrom is provided to wafer processing step S4. In wafer processing step S4, a semiconductor element is formed in semiconductor wafer 10 by formation of an impurity diffusion region in semiconductor wafer 10, formation of an insulating film or a gate on semiconductor wafer 10, formation of a wire on semiconductor wafer 10, or the like. Thus, a semiconductor device is formed.

### Effects of Laser Processing Apparatus 100

The effects of laser processing apparatus 100 will be described below.

In separation of outer circumferential portion 11 from semiconductor wafer 10 by application of laser beam L from the first surface 10a side, debris may adhere to second surface 10b if the liquid is not supplied to the second surface 10b side. After outer circumferential portion separation step S3, a tape is applied to second surface 10b. At this time, any debris adhering to second surface 10b can hinder application of the tape to second surface 10b.

In outer circumferential portion separation step S3 using laser processing apparatus 100, nozzle 50 supplies liquid 51 from the second surface 10b side to the portion of semiconductor wafer 10 irradiated with laser beam L. The debris that has occurred on second surface 10b is washed away with liquid 51, which reduces adhering of the debris to second surface 10b after outer circumferential portion separation step S3.

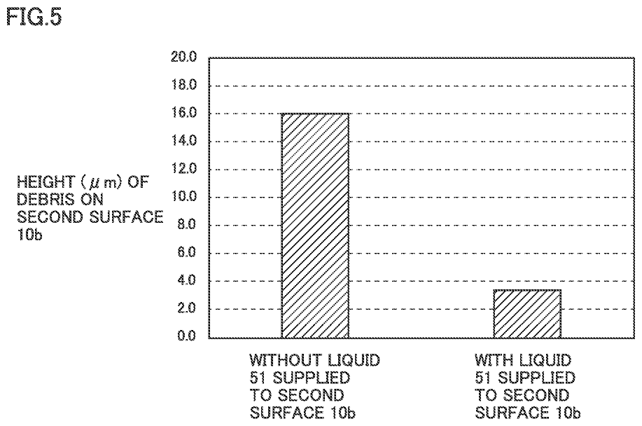

FIG. 5 is a graph showing heights of debris that adheres to second surface 10b when liquid 51 is supplied from the second surface 10b side and when liquid 51 is not supplied from the second surface 10b side. The vertical axis of FIG. 5 indicates a height (unit: μm) of debris that adheres to second surface 10b after outer circumferential portion separation step S3. As shown in FIG. 5, when liquid 51 is not supplied from the second surface 10b side, the height of debris that adheres to second surface 10b after outer circumferential portion separation step S3 is more than 10 μm. If the height of debris that adheres to second surface 10b is more than 10 μm, application of the tape to second surface 10b is hindered.

In contrast, when liquid 51 is supplied from the second surface 10b side, the height of debris that adheres to second surface 10b after outer circumferential portion separation step S3 is less than 10 μm and is approximately 3 μm. Thus, when liquid 51 is supplied from the second surface 10b side, application of the tape to second surface 10b is not hindered. The comparison above shows that laser processing apparatus 100 reduces adhering of debris to second surface 10b, which does not hinder the application of the tape to second surface 10b after outer circumferential portion separation step S3.

### Embodiment 2

A laser processing apparatus according to Embodiment 2 will be described. The laser processing apparatus according to Embodiment 2 is referred to as a laser processing apparatus 200. Differences from laser processing apparatus 100 will be mainly described, and redundant description will not be repeated.

### Configuration of Laser Processing Apparatus 200

A configuration of laser processing apparatus 200 will be described below.

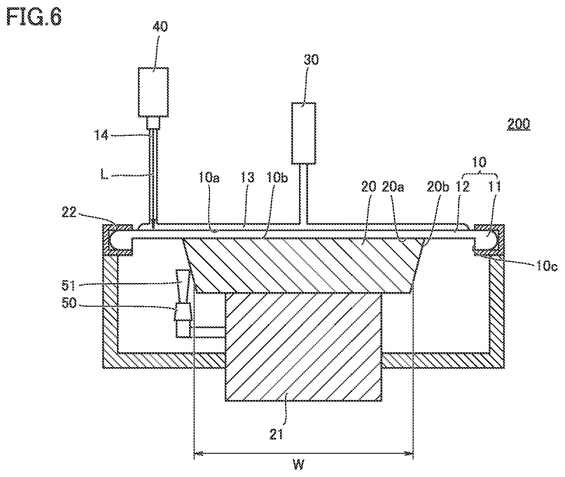

FIG. 6 is a schematic sectional view of laser processing apparatus 200. As shown in FIG. 6, laser processing apparatus 200 includes stage 20, driver 21, clamping mechanism 22, liquid supply mechanism 30, laser irradiation mechanism 40, and nozzle 50. Laser processing apparatus 200 is used to separate outer circumferential portion 11 from semiconductor wafer 10. In these respects, the configuration of laser processing apparatus 200 is similar to the configuration of laser processing apparatus 100.

The width of side surface 20b is referred to as a width W. Width W is a width of side surface 20b in a sectional view passing through, and parallel to, the axis of rotation of stage 20. In laser processing apparatus 200, width W increases toward wafer holding surface 20a.

In laser processing apparatus 200, as liquid 51 is sprayed toward side surface 20b, liquid 51 is supplied to the portion of semiconductor wafer 10, irradiated with laser beam L, from the second surface 10b side. In these respects, the configuration of laser processing apparatus 200 is different from the configuration of laser processing apparatus 100.

### Method of Manufacturing Semiconductor Device Using Laser Processing Apparatus 200

A method of manufacturing a semiconductor device using laser processing apparatus 200 will be described below.

The method of manufacturing a semiconductor device using laser processing apparatus 200 includes preparation step S1, semiconductor wafer processing step S2, outer circumferential portion separation step S3, and wafer processing step S4. In this respect, the method of manufacturing a semiconductor device using laser processing apparatus 200 is similar to the method of manufacturing a semiconductor device using laser processing apparatus 100.

In the method of manufacturing a semiconductor device using laser processing apparatus 200, liquid 51 is sprayed toward side surface 20b in outer circumferential portion separation step S3. In this respect, the method of manufacturing a semiconductor device using laser processing apparatus 200 is different from the method of manufacturing a semiconductor device using laser processing apparatus 100.

### Effects of Laser Processing Apparatus 200

The effects of laser processing apparatus 200 will be described below.

When liquid 51 is directly supplied to the portion of semiconductor wafer 10, irradiated with laser beam L, from the second surface 10b side, an impact is applied to the portion of semiconductor wafer 10, irradiated with laser beam L, by spraying of liquid 51.

In laser processing apparatus 200, liquid 51 is sprayed toward side surface 20b. Since side surface 20b is inclined such that width W increases toward wafer holding surface 20a, liquid 51 sprayed to side surface 20b reaches second surface 10b located at inner circumferential portion 12 along the inclination. Liquid 51 that has reached second surface 10b located at inner circumferential portion 12 reaches the portion of semiconductor wafer 10, irradiated with laser beam L, by the centrifugal force associated with the rotation of stage 20.

Thus, laser processing apparatus 200 can supply liquid 51 to the portion of semiconductor wafer 10 irradiated with laser beam L without directly spraying liquid 51 to the portion of semiconductor wafer 10 irradiated with laser beam L, thereby reducing application of an impact to the portion of semiconductor wafer 10 irradiated with laser beam L.

### Embodiment 3

A laser processing apparatus according to Embodiment 3 will be described. The laser processing apparatus according to Embodiment 3 is referred to as a laser processing apparatus 300. Differences from laser processing apparatus 100 will be mainly described, and redundant description will not be repeated.

### Configuration of Laser Processing Apparatus 300

A configuration of laser processing apparatus 300 will be described below.

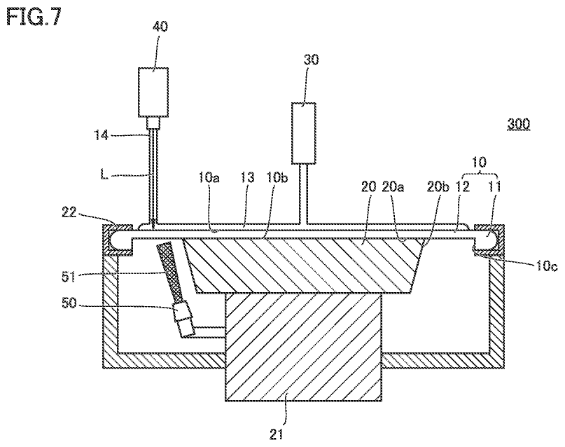

FIG. 7 is a schematic sectional view of laser processing apparatus 300. As shown in FIG. 7, laser processing apparatus 300 includes stage 20, driver 21, clamping mechanism 22, liquid supply mechanism 30, laser irradiation mechanism 40, and nozzle 50. Laser processing apparatus 300 is used to separate outer circumferential portion 11 from semiconductor wafer 10. In these respects, the configuration of laser processing apparatus 300 is similar to the configuration of laser processing apparatus 100.

In laser processing apparatus 300, nozzle 50 sprays liquid 51 in an atomized state. Liquid 51 is sprayed in an atomized state by, for example, a mesh material attached to the opening of nozzle 50. In these respects, the configuration of laser processing apparatus 300 is different from the configuration of laser processing apparatus 100.

### Method of Manufacturing Semiconductor Device Using Laser Processing Apparatus 300

A method of manufacturing a semiconductor device using laser processing apparatus 300 will be described below.

The method of manufacturing a semiconductor device using laser processing apparatus 300 includes preparation step S1, semiconductor wafer processing step S2, outer circumferential portion separation step S3, and wafer processing step S4. In this respect, the method of manufacturing a semiconductor device using laser processing apparatus 300 is similar to the method of manufacturing a semiconductor device using laser processing apparatus 100. In the method of manufacturing a semiconductor device using laser processing apparatus 300, nozzle 50 sprays liquid 51 in an atomized state in outer circumferential portion separation step S3. In this respect, the method of manufacturing a semiconductor device using laser processing apparatus 300 is different from the method of manufacturing a semiconductor device using laser processing apparatus 100.

### Effects of Laser Processing Apparatus 300

Effects of laser processing apparatus 300 will be described below.

In laser processing apparatus 300, liquid 51 in an atomized state can be supplied to the portion of semiconductor wafer 10 irradiated with laser beam L, thereby reducing application of an impact to the portion of semiconductor wafer 10 irradiated with laser beam L.

### Embodiment 4

A laser processing apparatus according to Embodiment 4 will be described. The laser processing apparatus according to Embodiment 4 is referred to as a laser processing apparatus 400. Differences from laser processing apparatus 100 will be mainly described, and redundant description will not be repeated.

### Configuration of Laser Processing Apparatus 400

A configuration of laser processing apparatus 400 will be described below.

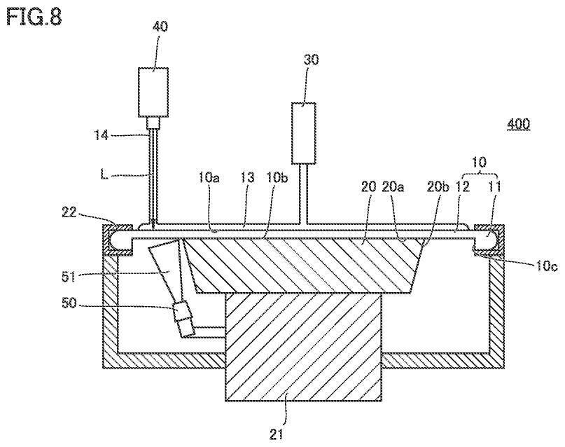

FIG. 8 is a schematic sectional view of laser processing apparatus 400. As shown in FIG. 8, laser processing apparatus 400 includes stage 20, driver 21, clamping mechanism 22, liquid supply mechanism 30, laser irradiation mechanism 40, and nozzle 50. Laser processing apparatus 400 is used to separate outer circumferential portion 11 from semiconductor wafer 10. In these respects, the configuration of laser processing apparatus 400 is similar to the configuration of laser processing apparatus 100. In laser processing apparatus 400, the opening edge of the opening of nozzle 50 has an elliptical shape. In this respect, the configuration of laser processing apparatus 400 is different from the configuration of laser processing apparatus 100.

### Method of Manufacturing Semiconductor Device Using Laser Processing Apparatus 400

A method of manufacturing a semiconductor device using laser processing apparatus 400 will be described below.

The method of manufacturing a semiconductor device using laser processing apparatus 400 includes preparation step S1, semiconductor wafer processing step S2, outer circumferential portion separation step S3, and wafer processing step S4. In this respect, the method of manufacturing a semiconductor device using laser processing apparatus 400 is similar to the method of manufacturing a semiconductor device using laser processing apparatus 100. In the method of manufacturing a semiconductor device using laser processing apparatus 400, since the opening edge of the opening of nozzle 50 has an elliptical shape, the range of spray of liquid 51 is wider in outer circumferential portion separation step S3. In this respect, the method of manufacturing a semiconductor device using laser processing apparatus 400 is different from the method of manufacturing a semiconductor device using laser processing apparatus 100.

### Effects of Laser Processing Apparatus 400

The effects of laser processing apparatus 400 will be described below.

In laser processing apparatus 400, liquid 51 is supplied to a wider range including the portion of semiconductor wafer 10 irradiated with laser beam L. This can reduce application of an impact to the portion of semiconductor wafer 10 irradiated with laser beam L and also reduce adhering of debris to second surface 10b in a wider range.

### NOTES

Aspects of the present disclosure will be described collectively as notes.

### <Note 1>

A laser processing apparatus comprising:

a stage having a wafer holding surface;

a laser irradiation mechanism; and

a nozzle, wherein

on the wafer holding surface, a semiconductor wafer having a first surface and a second surface opposite to the first surface is disposed such that the wafer holding surface faces the second surface,

the laser irradiation mechanism applies a laser beam from a first surface side, and

the nozzle supplies a liquid from a second surface side.

### <Note 2>

The laser processing apparatus according to note 1, wherein

the stage has a side surface contiguous to the wafer holding surface,

the stage is rotated about an axis of rotation running in a direction of a normal to the wafer holding surface,

the liquid is sprayed toward the side surface, and

the side surface has a width increasing toward the wafer holding surface.

### <Note 3>

The laser processing apparatus according to note 1 or 2, wherein the nozzle sprays the liquid in an atomized state.

### <Note 4>

The laser processing apparatus according to any one of notes 1 to 3, wherein

the nozzle has an opening from which the liquid is sprayed, and

an opening edge of the opening has an elliptical shape.

### <Note 5>

A method of manufacturing a semiconductor device, the method comprising:

preparing a semiconductor wafer having a first surface and a second surface opposite to the first surface, the semiconductor wafer having an outer circumferential portion and an inner circumferential portion located inside the outer circumferential portion;

processing the second surface located at the inner circumferential portion to be recessed toward the first surface;

disposing the semiconductor wafer on a wafer holding surface of a stage such that the second surface faces the wafer holding surface; and

applying a laser beam from a first surface side while supplying a liquid from a second surface side, to separate the outer circumferential portion from the semiconductor wafer.

### <Note 6>

The method of manufacturing a semiconductor device according to claim 5, wherein

the stage has a side surface contiguous to the wafer holding surface,

the stage is rotated about an axis of rotation running in a direction of a normal to the wafer holding surface,

the liquid is sprayed toward the side surface, and

the side surface has a width increasing toward the wafer holding surface.

### <Note 7>

The method of manufacturing a semiconductor device according to note 5 or 6, wherein the liquid is sprayed in an atomized state.

### <Note 8>

The method of manufacturing a semiconductor device according to any one of notes 5 to 7, wherein

the liquid is sprayed from an opening of a nozzle, and

an opening edge of the opening has an elliptical shape.

Although the embodiments of the present invention have been described, it should be understood that the embodiments disclosed herein are illustrative and non-restrictive in every respect. The scope of the present invention is defined by the terms of the claims and is intended to include any modifications within the scope and meaning equivalent to the terms of the claims.

What is claimed is:

1. A laser processing apparatus comprising:
a stage having a wafer holding surface;
a laser irradiation mechanism; and
a nozzle, wherein
on the wafer holding surface, a semiconductor wafer having a first surface and a second surface opposite to the first surface is disposed such that the wafer holding surface faces the second surface,
the laser irradiation mechanism applies a laser beam from a first surface side, and
the nozzle supplies a liquid from a second surface side.

2. The laser processing apparatus according to claim 1, wherein
the stage has a side surface contiguous to the wafer holding surface,
the stage is rotated about an axis of rotation running in a direction of a normal to the wafer holding surface,
the liquid is sprayed toward the side surface, and
the side surface has a width increasing toward the wafer holding surface.

3. The laser processing apparatus according to claim 1, wherein the nozzle sprays the liquid in an atomized state.

4. The laser processing apparatus according to claim 1, wherein
the nozzle has an opening from which the liquid is sprayed, and
an opening edge of the opening has an elliptical shape.

5. The laser processing apparatus according to claim 2, wherein
the nozzle has an opening from which the liquid is sprayed, and
an opening edge of the opening has an elliptical shape.

6. The laser processing apparatus according to claim 3, wherein
the nozzle has an opening from which the liquid is sprayed, and
an opening edge of the opening has an elliptical shape.

7. A method of manufacturing a semiconductor device, the method comprising:
preparing a semiconductor wafer having a first surface and a second surface opposite to the first surface, the semiconductor wafer having an outer circumferential portion and an inner circumferential portion located inside the outer circumferential portion;
processing the second surface located at the inner circumferential portion to be recessed toward the first surface;
disposing the semiconductor wafer on a wafer holding surface of a stage such that the second surface faces the wafer holding surface; and
applying a laser beam from a first surface side while supplying a liquid from a second surface side, to separate the outer circumferential portion from the semiconductor wafer.

8. The method of manufacturing a semiconductor device according to claim 7, wherein
the stage has a side surface contiguous to the wafer holding surface,
the stage is rotated about an axis of rotation running in a direction of a normal to the wafer holding surface,
the liquid is sprayed toward the side surface, and
the side surface has a width increasing toward the wafer holding surface.

9. The method of manufacturing a semiconductor device according to claim 7, wherein the liquid is sprayed in an atomized state.

10. The method of manufacturing a semiconductor device according to claim 7, wherein
the liquid is sprayed from an opening of a nozzle, and
an opening edge of the opening has an elliptical shape.

11. The method of manufacturing a semiconductor device according to claim 8, wherein
the liquid is sprayed from an opening of a nozzle, and
an opening edge of the opening has an elliptical shape.

12. The method of manufacturing a semiconductor device according to claim 9, wherein
the liquid is sprayed from an opening of a nozzle, and
an opening edge of the opening has an elliptical shape.
